(19) United States
(12) Patent Application Publication
(10) Pub. No.: US 2012/0299614 A1
(43) Pub. Date: Nov. 29, 2012

(54) Test socket with a rapidly detachable electrical connection module

(75) Inventor: Mike Wu, Taoyuan County (TW)

(73) Assignee: Tek Crown Technology Co., Ltd.

(21) Appl. No.: 13/200,264

(22) Filed: Sep. 22, 2011

(30) Foreign Application Priority Data
May 27, 2011 (TW) 100209557

(51) Int. Cl. G01R 31/00

(52) U.S. Cl. 324/756.02

(57) ABSTRACT

A test socket includes a test base and at least one electrical connection module. The at least one electrical connection module is detachably mounted in the test base and each one of the at least one electrical connection module has a frame and an electrically conducting element. The frame has a receiving hole for receiving and testing an IC. The electrically conducting element is detachably mounted on a bottom of the frame. After long time of use, the ineffective electrical connection module or electrically conducting element thereof can be rapidly and easily replaced with a new or an effective one by directly detaching the electrical connection module from the test base. Therefore, idle time or dead time of test apparatuses is shortened and test efficiency is enhanced.

### BACKGROUND OF THE INVENTION

1. Field of the Invention

The present invention relates to a test socket, and more particularly to a test socket with a rapidly detachable electrical connection module.

2. Description of the Prior Arts

Test sockets mounted on manual or automated test apparatuses are used for receiving and testing integrated circuit (IC). A conventional test socket comprises a test base and an electrically conducting element. The test base includes a receiving hole for receiving and testing an IC. The electrically conducting element is mounted on a bottom of the test base and the test base is then screwed to a load board of a test apparatus to hold the electrically conducting element. The electrically conducting element serves as an electrically conducting medium between the IC and the load board of the test apparatus and includes multiple input and output terminals respectively electrically connected to corresponding contact pads of the load board.

When tested, the IC is put in the receiving hole of the test base and is then subjected to a pressing force by an operator's hand or a robot. Under this circumstance, input and output terminals (e.g. terminal pins, terminal pads, ball terminals or the like) on a bottom surface of the IC abut against the input and output terminals of the electrically conducting element and are electrically connected to the test apparatus through an electrical connection with the contact pads on the load board. Thus, the test apparatus can test the IC to determine if the IC functions correctly.

The electrically conducting element will become dirty and lose its elasticity and electrical characteristic after being repeatedly subjected to the pressing forces. To ensure accuracy of test results, the electrically conducting element must be taken out of the test apparatus and be replaced with a new or an effective one after long time of use. Conventionally steps for replacing the electrically conducting element are stopping the test apparatus first, detaching the test base from the load board, then mounting a new or an effective electrically conducting element on the test base and finally re-screwing the test base to the load board. In general, the test apparatus must be stopped for tens of minutes each replacement time and therefore test efficiency is reduced.

To overcome the shortcomings, the present invention provides a test socket with a rapidly detachable electrical connection module to mitigate or obviate the aforementioned problems.

### SUMMARY OF THE INVENTION

The main object of the present invention is to provide a test socket with a rapidly detachable electrical connection module for high test efficiency.

To achieve the foregoing objective, the test socket in accordance with the present invention comprises a test base and at least one electrical connection module. The test base includes a top surface, a bottom surface and a mounting hole. The mounting hole is formed through the test base and extends from the top surface to the bottom surface of the test base. The at least one electrical connection module is detachably mounted in the test base and each one of the at least one electrical connection module includes a frame and an electrically conducting element. The frame is detachably mounted in the mounting hole of the test base and has a top surface, a bottom surface and a receiving hole. The receiving hole is formed through the frame and extends from the top surface to the bottom surface of the frame for receiving and testing an IC. The electrically conducting element is detachably mounted on the bottom of the frame. After long time of use, the ineffective electrical connection module or electrically conducting element thereof can be rapidly and easily replaced with a new or an effective one by directly detaching the electrical connection module from the test base. Therefore, idle time or dead time of a test apparatus is shortened and test efficiency is enhanced.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a first embodiment of a test socket in accordance with the present invention;

FIG. 2 is an enlarged cross-sectional side view of the test socket in FIG. 1;

FIG. 3 is an enlarged cross-sectional side view of a second embodiment of a test socket in accordance with the present invention;

FIG. 4 is an enlarged side view in partial section of a third embodiment of a test socket in accordance with the present invention;

FIG. 5 is an enlarged side view in partial section of a fourth embodiment of a test socket in accordance with the present invention;

FIG. 6 is an enlarged bottom view of a fifth embodiment of an electrical connection module in accordance with the present invention;

FIG. 7 is a perspective view of the test socket in FIG. 1 mounted on a load board and applied to a manual test apparatus;

FIG. 8 is a perspective view of multiple test sockets in FIG. 1 mounted on the load boards and applied to an automated test apparatus;

FIG. 9 is an enlarged side view in partial section of the test socket in FIG. 1 with an IC under test; and

FIG. 10 is an operational cross-sectional side view of the test socket in FIG. 1 showing that an electrical connection module is being replaced with a new or an effective one.

### DETAILED DESCRIPTION OF THE PREFERRED EMBODIMENTS

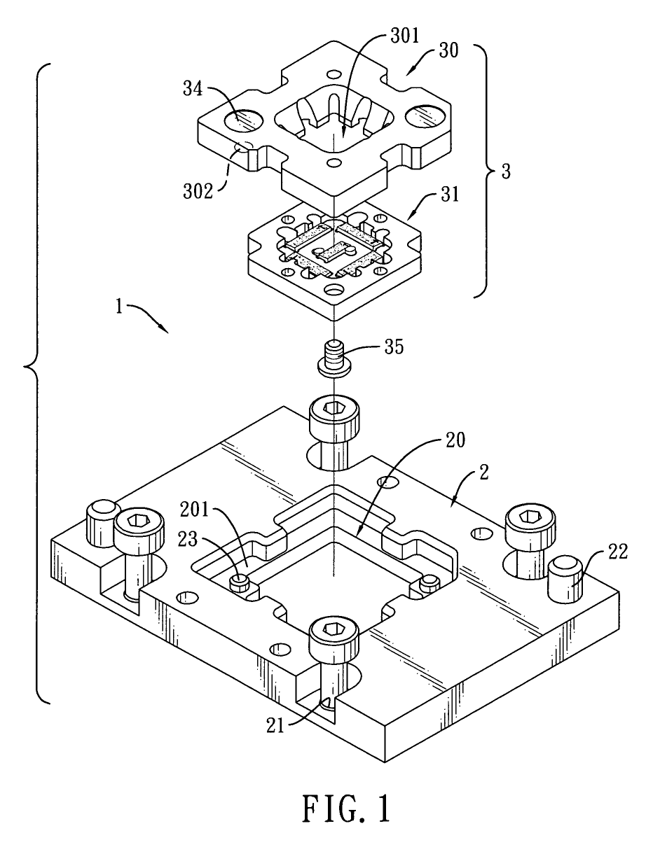

With reference to FIG. 1, a test socket 1 in accordance with the present invention comprises a test base 2 and at least one electrical connection module 3.

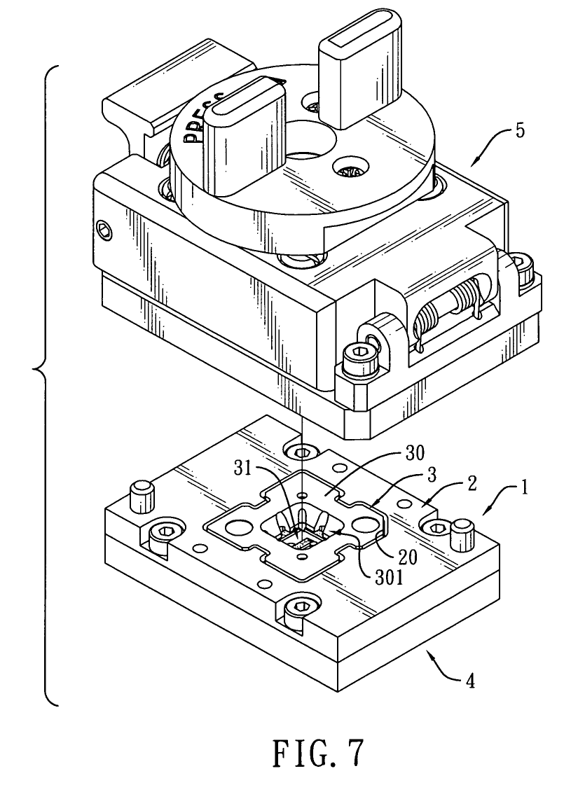

The test base 2 includes a top surface, a bottom surface, a mounting hole 20, multiple locating holes 21, multiple connecting columns 22 and at least one positioning pin 23. The mounting hole 20 is formed through the test base 2, extends from the top surface to the bottom surface of the test base 2 and has an upper portion, a lower portion and a step surface 201. A hole diameter of the upper portion is larger than a hole diameter of the lower portion. The step surface 201 is formed between the upper portion and the lower portion. The locating holes 21 are respectively formed through the test base 2 around the mounting hole 20. Screws are mounted through the locating holes 21 and a load board 4 to fix the test base 2 on the load board 4 (with reference to FIG. 7). The connecting columns 22 respectively protrude from the top surface of the test base 2 for assembling with a test apparatus. Each one of the at least one positioning pin 23 protrudes from the step surface 201 of the mounting hole 20.

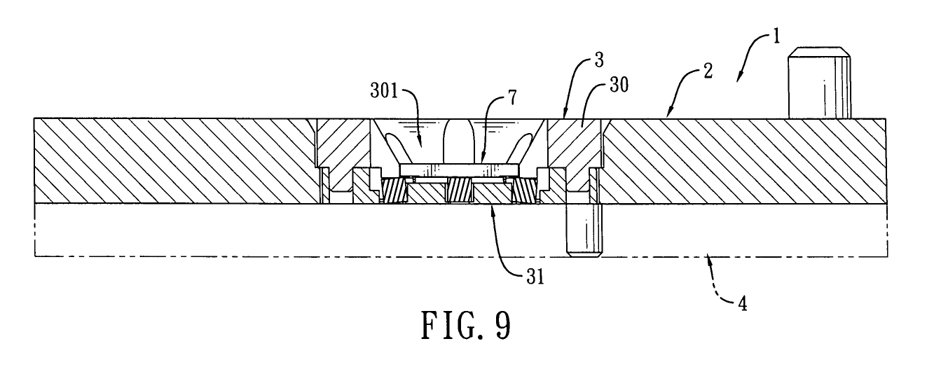

The at least one electrical connection module 3 is detachably mounted in the test base 2 and each one of the at least one electrical connection module 3 includes a frame 30 and an electrically conducting element 31. The frame 30 corresponds to and is detachably mounted in the upper portion of the mounting hole 20 of the test base 2 and has a top surface, a bottom surface, a receiving hole 301 and at least one positioning hole 302. The receiving hole 301 is formed through the frame 30 and extends from the top surface to the bottom surface of the frame 30 for receiving and testing an IC 7 (with reference to FIG. 9). Each one of the at least one positioning hole 302 is formed in the bottom surface of the frame 30 for receiving a corresponding positioning pin 23 of the test base 2. In a preferred embodiment, the positioning pin 23 of the test base 2 is made of iron and the frame 30 further has at least one magnet 34. Each one of the at least one magnet 34 is mounted on the frame 30 over a corresponding positioning hole 302 for attracting the positioning pin 23 of the test base 2 so as to securely hold the frame 30 on the test base 2. Also, the frame 30 may be held on the test base 2 by screws.

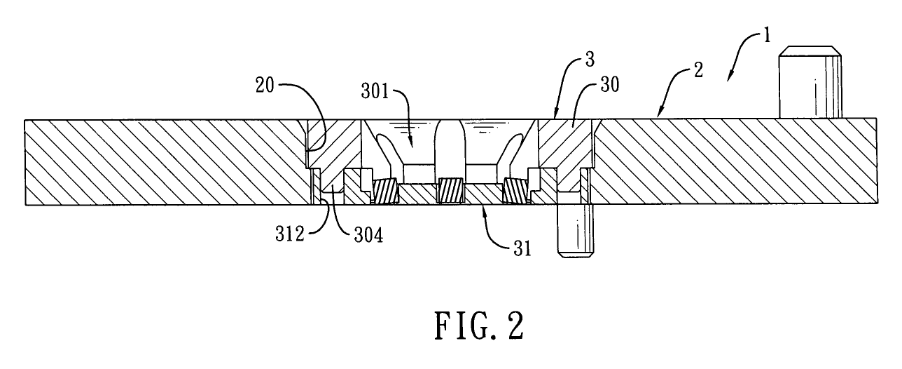

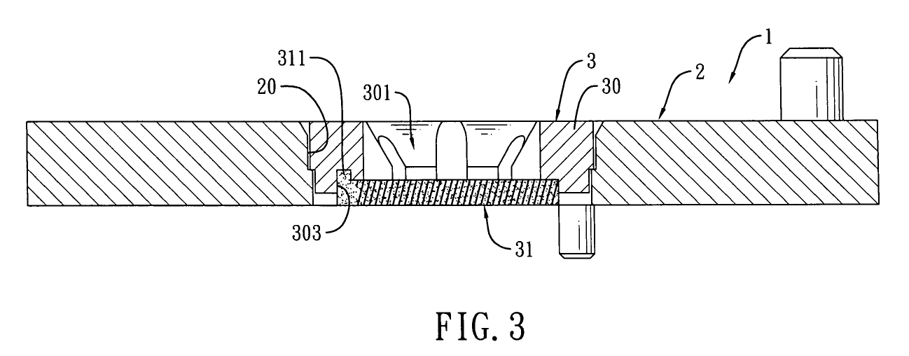

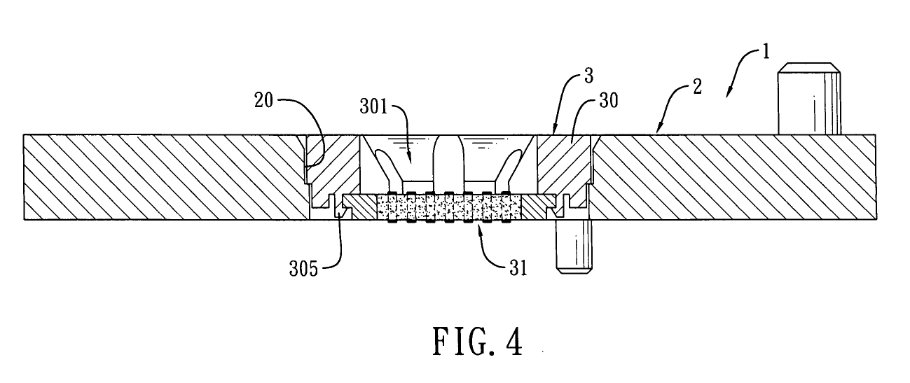

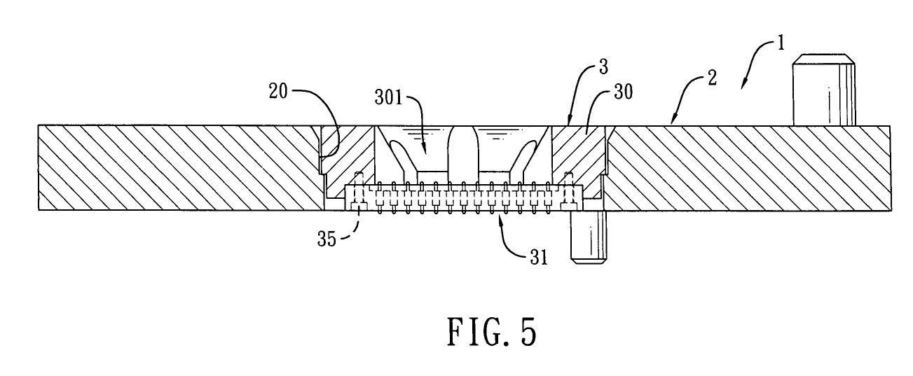

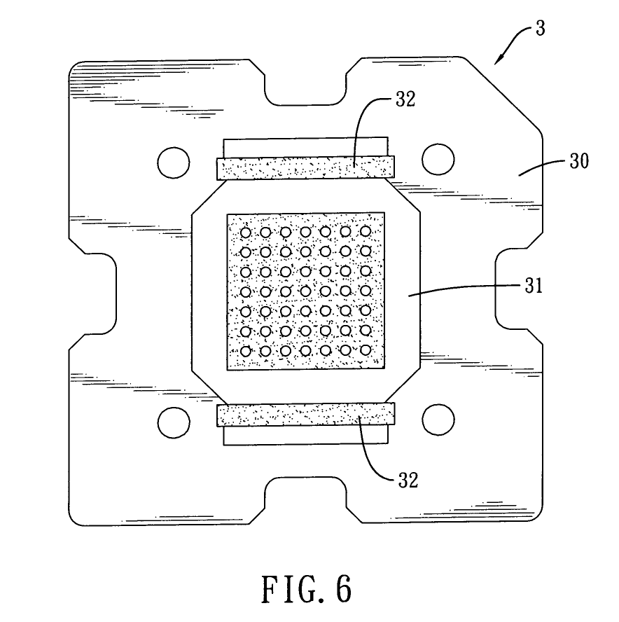

The electrically conducting element 31 is detachably mounted on a bottom of the frame 30, is located at the lower portion of the mounting hole 20 of the test base 2 and has multiple input and output terminals. The electrically conducting element 31 may be a carrier having multiple conductive elements as shown in FIGS. 1 and 2, may be a conductive elastomer having multiple lead wires as shown in FIG. 3, may be a conductive elastomer having multiple columnar conductive particles as shown in FIG. 4, and may be a carrier having multiple telescopic conductive probes arranged in an array as shown in FIG. 5 or any other elements having electrical conduction functions from top to bottom. The said conductive elements, lead wires, conductive particles and conductive probes are used as input and output terminals. The electrically conducting element 31 may be held on the frame 30 by positioning pins, by screws 35 as shown in FIGS. 1 and 5, by recesses 312,303 receiving protrusions 304,311 as shown in FIGS. 2 and 3, by hooks 305 of the frame 30 engaging the electrically conducting element 31 as shown in FIG. 4 or by elastomers 32 mounted on the bottom surface of the frame 30 and abutting sides of the electrically conducting element 31 as shown in FIG. 6.

With reference to FIG. 7, the test socket 1 in accordance with the present invention is applied to a manual test apparatus, and the test socket 1 is fixed on the load board 4 of the manual test apparatus to make bottom ends of the input and output terminals of the electrically conducting element 31 respectively electrically connected to corresponding contact pads of the load board 4. With further reference to FIG. 9, when ICs 7 are tested, an operator puts the IC 7 in the receiving hole 301 of the frame 30 and then covers the test socket 1 with a test cover 5 and exerts a pressing force to the IC 7. Under this circumstance, input and output terminals on a bottom surface of the IC 7 abut against the input and output terminals of the electrically conducting element 31 and are electrically connected to the manual test apparatus through an electrical connection with the load board 4. Thus, the manual test apparatus can test the IC 7.

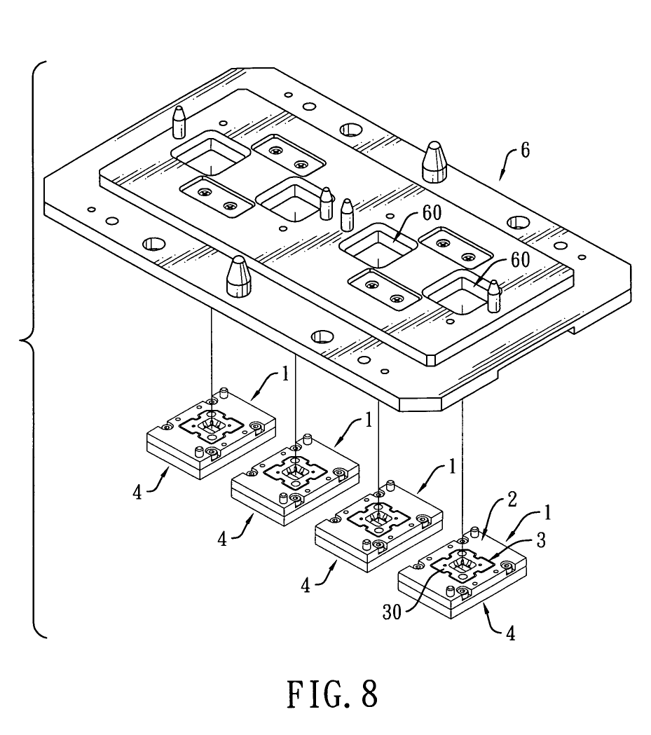

With reference to FIG. 8, multiple test sockets 1 in accordance with the present invention are applied to an automated test apparatus, and the test sockets 1 are fixed on the load boards 4 of the automated test apparatus to make bottom ends of the input and output terminals of the electrically conducting element 31 respectively electrically connected to corresponding contact pads of the load board 4. The test bases 2 of the test sockets 1 are respectively connected to a bottom of a connecting board 6 to make each electrical connection module 3 correspond to a hole 60 of the connecting board 6. The connecting board 6 is mounted on a body of the automated test apparatus. With reference to FIG. 9, when ICs 7 are tested, each IC 7 is picked up and is then positioned and pressed in a corresponding receiving hole 301 of the frame 30 by a robot of the automated test apparatus. Under this circumstance, input and output terminals on a bottom surface of the IC 7 abut against the input and output terminals of the electrically conducting element 31 and are electrically connected to the automated test apparatus through an electrical connection with the load board 4. Thus, the automated test apparatus can test the ICs 7.

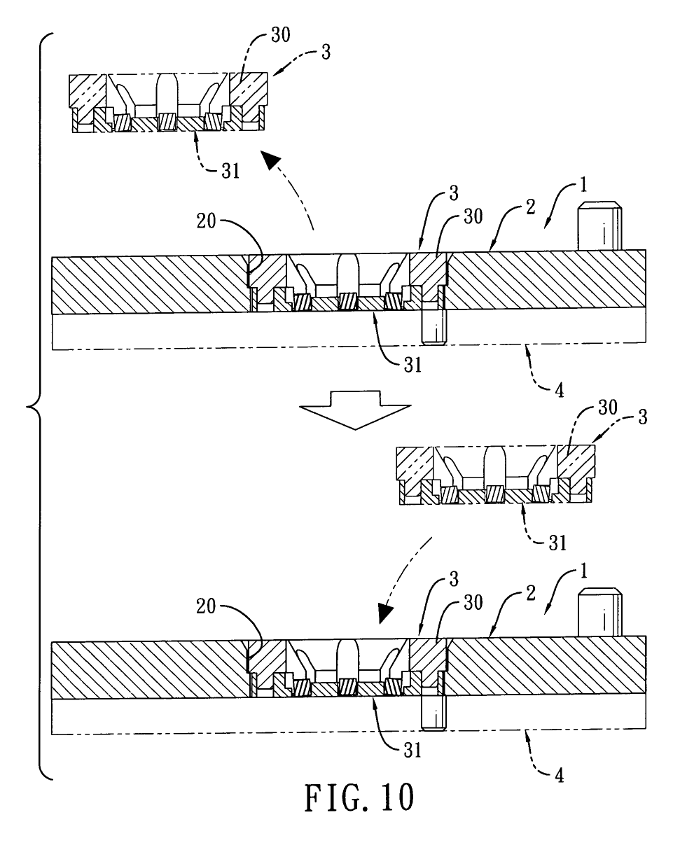

When the electrically conducting element 31 becomes dirty and loses its elasticity and electrical characteristic after being repeatedly subjected to the pressing forces, the electrically conducting element 31 needs to be replaced. With reference to FIG. 10, the electrical connection module 3 with the ineffective electrically conducting element 31 is directly taken out from the test base 2 by a hand tool or a robot and a new or an effective electrical connection module 3 is then mounted in the test base 2, or the electrical connection module 3 is directly taken out from the test base 2, the ineffective electrically conducting element 31 is then replaced with a new or an effective one and the electrical connection module 3 with the new electrically conducting element 31 is remounted in the test base 2. Consequently, idle time or dead time of test apparatuses is shortened and test efficiency is enhanced because operators can easily and rapidly detach the electrical connection module 3 from the test base 2 and detach the electrically conducting element 31 from the electrical connection module 3.

Even though numerous characteristics and advantages of the present invention have been set forth in the foregoing description, together with details of the structure and features of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A test socket comprising:
a test base including
a top surface;
a bottom surface; and
a mounting hole formed through the test base and extending from the top surface to the bottom surface of the test base; and
at least one electrical connection module detachably mounted in the test base and each one of the at least one electrical connection module including
a frame detachably mounted in the mounting hole of the test base and having
a top surface;
a bottom surface;
a receiving hole formed through the frame and extending from the top surface to the bottom surface of the frame; and
an electrically conducting element detachably mounted on a bottom of the frame and having multiple input and output terminals.

2. The test socket as claimed in claim 1, wherein the electrically conducting element is held on the frame by recesses receiving protrusions.

3. The test socket as claimed in claim 1, wherein the electrically conducting element is held on the frame by hooks of the frame engaging the electrically conducting element.

4. The test socket as claimed in claim 1, wherein the electrically conducting element is held on the frame by screws.

5. The test socket as claimed in claim 1, wherein the electrically conducting element is held on the frame by elastomers mounted on the bottom surface of the frame and abutting sides of the electrically conducting element.

6. The test socket as claimed in claim 1, wherein the frame is held on the test base by a magnet.

7. The test socket as claimed in claim 2, wherein the frame is held on the test base by a magnet.

8. The test socket as claimed in claim 3, wherein the frame is held on the test base by a magnet.

9. The test socket as claimed in claim 4, wherein the frame is held on the test base by a magnet.

10. The test socket as claimed in claim 5, wherein the frame is held on the test base by a magnet.

11. The test socket as claimed in claim 1, wherein the frame is held on the test base by at least one positioning pin inserted into at least one positioning hole.

12. The test socket as claimed in claim 2, wherein the frame is held on the test base by at least one positioning pin inserted into at least one positioning hole.

13. The test socket as claimed in claim 3, wherein the frame is held on the test base by at least one positioning pin inserted into at least one positioning hole.

14. The test socket as claimed in claim 4, wherein the frame is held on the test base by at least one positioning pin inserted into at least one positioning hole.

15. The test socket as claimed in claim 5, wherein the frame is held on the test base by at least one positioning pin inserted into at least one positioning hole.
